(19) United States
(12) Patent Application Publication
(10) Pub. No.: US 2014/0264260 A1
(43) Pub. Date: Sep. 18, 2014

(54) LIGHT EMITTING STRUCTURE

(71) Applicant: DESIGN EXPRESS LIMITED, Tortola (VG)

(72) Inventors: Chun Yen CHANG, HSINCHU COUNTY (TW); Jet Rung CHANG, TAICHUNG CITY (TW)

(73) Assignee: DESIGN EXPRESS LIMITED, TORTOLA (VG)

(21) Appl. No.: 13/837,476

(22) Filed: Mar. 15, 2013

(51) Int. Cl. H01L 33/06; H01L 33/58

(52) U.S. Cl. CPC H01L 33/06; H01L 33/58
USPC 257/13; 438/22

(57) ABSTRACT

The present invention provides a semiconductor column structure which includes a light emitting layer and at least two facets with different crystalline orientations. The surface area ratio of the at least two facets is changed to alter the luminescence properties, such as CCT and CRI. Particularly, the surface area ratio of the at least two facets is adjusted in a range of from 1:0.1 to 1:10.

### FIELD OF THE INVENTION

The present invention relates to the structure of a monolithic light emitting diode (LED) emitting white light, and more particularly, to a poly-chromatic LED without phosphors.

### DISCUSSION OF THE BACKGROUND

The need and search for a white light LED follows a number of paths. One such path is the placement of three individual emitters—InGaN for blue and green, and AlGaInP for red—in close proximity so that their combinatorial output creates white light. But since individual control of the output power of each emitter is a necessary requirement in this application, the discrepancies between the operating voltage of InGaN-based LEDs and that of AlGaInP-based LEDs raise a challenge when used in application.

Previously, a better approach was the use of phosphor powder in conjunction with a high powered blue emitter; however, this solution required improvements to blue LED technology. Nichia Corporation became the first company to commercialize InGaN-based, blue LEDs with yellow phosphor [(Y₁₋ₐGdₐ)₃(Al_{1-b}Ga_{b})₅O₁₂:Ce³⁺(YAG)]. These phosphor-conversion white light LEDs represent an innovation in solid-state lighting despite having been used primarily for backlighting LCDs in the past. Though, with current increases in output power, they will eventually be used in flashlights and other sources of illumination. Continued research will lead to white light LEDs that can replace conventional incandescent and fluorescent lamps. However, phosphor-conversion white light LEDs have two practical downsides. First, coating the phosphor powder on the LED chip adds to manufacturing costs, and second, there is an unavoidable, approximately 30%-50%, energy loss due to the difference between the energy of the photons used to pump the phosphor and the energy of those emitted.

For this reason, a monolithic, phosphor-free approach has been investigated. A matrix of multiple micro planar areas arranged in a nano-pyramid array is one solution for substituting the phosphor-conversion white light LEDs. The emitted white light combines yellow emissions from InGaN multi-quantum wells (MQWs) on nano-pyramids and blue emissions from micron-sized planar areas. Two individual controls of the output power for the micron-sized planar areas and the nano-pyramids were necessary in this application.

Because the long term goal of white light LEDs is to replace conventional incandescent and fluorescent lamps, tuning of the white light luminescence properties is also a consideration in designing white light emitters. One of the white light luminescence properties, for example, is correlated color temperature (CCT). CCT of cool white light falls above 5000K, whereas the CCT of warm white light falls at around 3000K. The major difference between the two CCTs is the intensity ratio of the emitted cool color (blue or purple) and the emitted warm color (orange or red). To provide another example of the white light luminescence properties, color rendering index (CRI) is a quantitative measure of the ability of a light source to reproduce the colors of various objects faithfully in comparison with an ideal or natural light source. Light sources with a high CRI are desirable in color-critical applications such as photography and cinematography. However, a solution to tuning the luminescence property of a monolithic, phosphor-free white light LED has not been disclosed specifically.

For the phosphor-conversion white light LEDs, tuning of the desired CCT and CRI can be achieved by adjusting the power of the blue LED and the composition/quantity of the yellow phosphor powder. As shown in FIG. 1A, the intensity ratio of the blue peak at 450 nm and the broad peak centered at 550 nm is larger than 1, whereas in FIG. 1B, not only the intensity ratio between the two peaks is closer to 1, but also the peak wavelength of the broad peak is slightly shifted to the longer end. Consequently, light emitting diodes (LEDs) having spectrums as shown in FIG. 1A emit standard cold white light with a CCT of 5500K, and said LEDs are suitable to replace fluorescent light bulbs. LEDs having spectrums as shown in FIG. 1B emit warm white light with a CCT of 3000K, and said LEDs are normally used to supplant incandescent light bulbs or natural daylight.

### SUMMARY

One aspect of the present invention is to provide a semiconductor column structure which includes a light emitting layer; and at least two facets with different crystalline orientations. The surface area ratio of the at least two facets is proposed to change the luminescence properties, such as CCT and CRI. Particularly, the surface area ratio of the at least two facets is in a range of from 1:0.1 to 1:10.

One embodiment of the present disclosure provides a semiconductor column structure with one multi-quantum well (MQW). The other embodiment of the present disclosure provides a semiconductor column structure with two MQWs, wherein the two MQWs are designed to possess different emitting wavelengths.

One embodiment of the present disclosure provides a semiconductor column structure with two facets; one of which is the non-polar sidewall facets of {1 ^{1̅} 00} family (i.e. the “M” plane); and the other is the semi-polar facets of {10 ^{1̅} 1} family (i.e. the “S” plane). The non-polar “M” plane can be at the sidewall of a hexagonal column, whereas the semi-polar “S” plane can be at the face of a hexagonal pyramid on the top of the hexagonal column. The diameter of the hexagonal column in the present embodiment can be in the nanometer range, and the preferred surface ratio of S to M planes is in a range of from 1:1 to 1:3.

Another embodiment of the present disclosure provides a semiconductor column structure with two facets; one of which is the polar sidewall facets of {0001} family (i.e. the “C” plane); and the other is the semi-polar facets of {10 ^{1̅} 1} family (i.e. the “S” plane). The polar “C” plane can be at the top of a truncated hexagonal pyramid, whereas the semi-polar “S” plane can be at the side of a truncated hexagonal pyramid. The diameter of the bottom of the truncated hexagonal pyramid in the present embodiment can be in the micrometer range, and the preferred surface ratio of C to S planes is in a range of from 1:3 to 1:9.

Yet another embodiment of the present disclosure provides a semiconductor column structure with three facets; one of which is the polar sidewall facets of {0001} family (i.e. the “C” plane); another is the semi-polar facets of {10 1̅ 1} family (i.e. the “S” plane) and another is the non-polar facets of {1 1̅ 00} family (i.e. the “M” plane). The polar “C” plane can be at the top of a truncated hexagonal pyramid on a hexagonal column, whereas the semi-polar “S” plane can be at the side face of the truncated hexagonal pyramid. The “M” plane can be the sidewall of the hexagonal column. The diameter of the hexagonal column in the present embodiment can be in the micrometer range, and the preferred surface ratio of the C plane and the S plane is in a range of from 1:0.3 to 1:9, and the preferred surface area ratio of the C plane and the M plane is in a range of from 1:1 to 1:9.

The correlated color temperature (CCT) and the color rendering index (CRI) of the light emitting from each semiconductor column structure described in the present disclosure can be tuned by adjusting the surface area ratio between each crystallography plane or by adjusting the growth temperature of the light emitting layer of the semiconductor column structure. But, this is preferably but not limited to the designated range.

One embodiment of the present disclosure provides a light emitting diode structure, including a column array, a cathode electrically coupled to a first conductive type of the column array, and an anode electrically coupled to a second conductive type of the column array. Each column of the column array includes a truncated hexagonal pyramid structure and/or a pyramid structure as described in the aforesaid paragraphs, and adjusting the surface area ratio of the at least two facets is allowed to change the CCT and the CRI of the light emitting diode structure.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1A illustrates a spectrum of a cold white light source;

FIG. 1B illustrates a spectrum of a warm white light source;

FIG. 2 illustrates a top view of a light emitting diode structure having the column array according to one embodiment of the present invention;

FIG. 3 shows a perspective view of the column array according to one embodiment of the present invention;

FIG. 4A to FIG. 4D show the manufacturing process flow of the column array according to one embodiment of the present invention;

FIG. 5A and FIG. 5B show the cross-sectional and the perspective views of an embodiment according to one embodiment of the present invention;

FIG. 6A and FIG. 6B show the cross-sectional and the perspective views of an embodiment according to one embodiment of the present invention;

FIG. 7A and FIG. 7B show the cross-sectional and the perspective views of embodiments according to one embodiment of the present invention;

FIG. 8A and FIG. 8B show the cross-sectional and the perspective views of embodiments according to one embodiment of the present invention;

FIG. 9A and FIG. 9B illustrate a cross-sectional view of a column structure and the corresponding photoluminescence emission according to one embodiment of the present invention; and

FIG. 10A and FIG. 10B show the photoluminescence spectra of two column structures according to two embodiments of the present invention.

### DETAILED DESCRIPTION

FIG. 2 illustrates a top view of a light emitting diode structure 20 having a cathode 21 electrically connected to a first conductive type (for example, p-type) of a column array 23, and an anode 22 electrically connected to a second conductive type (for example, n-type) of the column array 23. Note a transparent electrode 25, for example, indium tin oxide (ITO), is positioned between the cathode 21 and the column array 23. The scale of each column of the column array 23 can be in the nanometer range or micrometer range with respect to the diameter of the cross-section that is normal to the axial direction of the column. For example, FIG. 3 shows a close-up view of a portion of the nanometer range column array 30 captured from the area 24 of FIG. 2. The column array 30 shown in FIG. 3 can be further characterized to have a hexagonal column 31 and a hexagonal pyramid 32 on the hexagonal column 31. Two distinct facets 311 and 321 compose the sidewalls of the hexagonal column 31 and the triangular faces of the hexagonal pyramid 32, respectively. The total surface area of the facet 321, which includes six triangular faces of the hexagonal pyramid 32, is designated as A, and the total surface area of the facet 311, which includes six rectangular sidewalls of the hexagonal column 31, is designated as B. The ratio of the aforesaid A and B is within a range of from 1:0.1 to 1:10, preferably within a range of from 1:1 to 1:3.

In FIG. 3, the front row columns are illustrated in a cross-sectional view, and sectioned along the axial direction of each column. Each column shows a core-shell structure having a pillar-like core 33 and an outer shell 34, wherein the diameter of the pillar-like core 33 can be in the nanometer range, and the outer shell 34 includes a partial shape of the hexagonal column 31 and a partial shape of the hexagonal pyramid 32. An oxide layer 35 is formed on the semiconductor layer 33′, and the outer shell 34 is further deposited on the surface of each column.

FIG. 4A to FIG. 4D show the manufacturing process flow of the column array 30 in FIG. 3 according to one embodiment of the present invention. In FIG. 4A, a semiconductor layer 402 is formed on the substrate 401 (note the thickness of these two layers is not illustrated in proportion). To achieve an improved dimension and pattern control, a circular etching mask array 403 (particularly silicon oxide nano disks having 350 nm in diameter with a center-to-center spacing of 800 nm) is patterned on the semiconductor 402 through imprint lithography as shown in FIG. 4B. The disks are then used as hard masks in an inductive, coupled plasma reactive ion etch (ICP-RIE) that etches down the exposed semiconductor layer 402 and forms pillars 404 about 1.0 μm in height, as shown in FIG. 4C. The semiconductor layer in this embodiment can be made of III-V semiconductor materials, preferably III-nitride materials. The disks are subsequently removed by buffer oxide etch (BOE). However, the diameter of the pillars 404 and the center-to-center spacing thereof are not limited to the size described above. In another embodiment, the diameter of the pillars is about 1 μm and the center-to-center spacing thereof is about 3 μm. An oxide layer 407 is formed on the semiconductor layer 402, for example, by a blanket deposition of oxide materials on the array of pillars 404 and on the surface of the semiconductor layer 402, followed by an etch to remove the oxide materials from the sidewall of the pillars 404.

FIG. 4D shows an enlarged view of one pillar 404 undergoing a regrowth process. An epitaxial layer 405 is deposited on the pillar 404, covering the outer surface thereof. The growth condition of the epitaxial layer 405 is adjusted to form two facets including {10 1̅ 1} and {10 1̅ 0}. The method controlling facet formation includes adjusting the growth temperature, the III/V ratio (if III-V materials were used), or the pressure in the growth chamber. The above-mentioned methods are considered common operational knowledge available in the current art. GaN is used as the regrowth material and a lower growth temperature is intentionally chosen to form a hexagonal pyramid on the top of the pillar 404. In the present embodiment, a growth temperature between 750° C. and 850° C. can be used, preferably at 805° C. Multiple pairs of multi-quantum wells (MQWs) 406 are subsequently formed on the GaN epitaxial layer 405 which had been regrown. In this embodiment, six pairs of InGaN/GaN MQWs are grown at 700° C. for wells and 805° C. for barriers, respectively. The growth pressure for the MQWs is 300 mbar, and the fluxes of tri-methyl indium (TMIn) and tri-methyl gallium (TMGa) are 250 and 76 sccm, respectively. The growth temperature of the wells is considered lower than usual because a higher InN fraction is desired in the InGaN wells.

A structure identical to the column array 30 is formed following FIG. 4D. As shown in FIG. 3, the regrown GaN epitaxial layer 405 and the MQW layers 406 are also formed on the semiconductor layer 33′. The growth condition of the GaN epitaxial layer 405 is controlled to meet the desired shape, which can be further characterized by the surface area ratio between different facets. For example, in a III-N materials system, the facets prone to be formed during the deposition on a column structure as described in the present invention can be classified into three categories, a polar C plane including crystalline orientations of {0001} family; a semi-polar S plane including crystalline orientations of {10 1̅ 2} family, {11 2̅ 2} family, and {1 1̅ 01} family; and a non-polar M plane including crystalline orientations of {1 1̅ 00} family. At least two facets with different crystalline orientations shall be formed by a proper growth condition, and the surface area ratio of said at least two facets shall be controlled within a range of from 1:0.1 to 1:10.

The MQW layer 406 consists of a plural pair of MQW structures, and is thus considered a light emitting layer. The well of the MQW structure can be indium-containing ternary alloy or indium-containing quaternary alloy. Due to different surface diffusion coefficients occurring on planes of different crystalline orientations, the indium concentration in the S plane, for example, can be lower than that in the M plane. Consequently, the alloy compositions composing wells of the MQW structure vary on planes of different crystalline orientations. In one embodiment, different facets of the column structure are able to emit different wavelengths because of the alloy composition variation in the wells of the MQW structure. On the other hand, the constraint on gas phase diffusion leads to an indium concentration change within a single plane of one crystalline orientation. As shown in FIG. 4D, the indium concentration at a first region 408 can be 25%, whereas the indium concentration at a second region 409 can be 11.6%. In one embodiment, the indium concentration continuously decreases with the region moving closer to the base of the column. Therefore, different regions on the same facets of the column structure are able to emit different wavelengths.

FIG. 5 to FIG. 8 show the cross-sectional and the perspective views of several embodiments in the present invention. FIG. 5A shows the cross-section of a column structure having a hexagonal column 51 and a hexagonal pyramid 52 on the hexagonal column 51, and FIG. 5B shows the three-dimensional view of the column structure according to the cross-sectional counterpart. Facet 511 composes the sidewalls of the hexagonal column 51, whereas facet 521 composes the triangular faces of the hexagonal pyramid 52. In particular, facet 521 is a semi-polar plane (S plane), including crystalline orientations of {10 1̅ 2} family, {11 2̅ 2} family, or {1 1̅ 01} family; facet 511 is a non-polar plane (M plane), including crystalline orientations of {1 1̅ 00} family. The pillar-like core 501 is covered by the outer shell 502, which can be the regrowth epitaxial layer described herein. A light-emitting layer 503 further covers the outer shell 502 and complies with the shape of the outer shell 502. In the present embodiment, there are six sets of MQWs in the light-emitting layer 503. The total surface area of the facet 521, which includes six triangular faces of the hexagonal pyramid 52, is denoted as C and the total surface area of the facet 511, which includes six rectangular sidewalls of the hexagonal column 51, is denoted as D. The ratio of the aforesaid C and D is within a range of from 1:1 to 1:3, preferably 1:1.8. In the present embodiment, the dimension W1, which is the widest distance on the cross-section perpendicular to the axial direction of the column structure, is in the nanometer range. In another embodiment, the dimension W1 can be in the micrometer range.

FIG. 6A shows the cross-section of a column structure having a hexagonal column 61 and a truncated hexagonal pyramid 62 on the hexagonal column 61, and FIG. 6B shows the three-dimensional view of the column structure according to the cross-sectional counterpart. Facet 611 composes the sidewalls of the hexagonal column 61, whereas facet 621 composes the quadrilateral faces of the truncated hexagonal pyramid 62. In particular, facet 621 is a semi-polar plane (S plane), including crystalline orientations of {10 1̅ 2} family, {11 2̅ 2} family, or {1 1̅ 01} family; facet 611 is a non-polar plane (M plane), including crystalline orientations of {1 1̅ 00} family; and facet 631 is a polar plane (C plane), including crystalline orientations of {0001} family. The pillar-like core 601 is covered by the outer shell 602, which can be the regrowth epitaxial layer described herein. A light-emitting layer 603 further covers the outer shell 602 and complies with the shape of the outer shell 602. In the present embodiment, there are six sets of MQWs in the light-emitting layer 603. The total surface area of the facet 621, which includes six quadrilateral faces of the truncated hexagonal pyramid 62, is denoted as E; the total surface area of the facet 611, which includes six rectangular sidewalls of the hexagonal column 61, is denoted as F; and the total surface area of the facet 631, which includes the hexagonal top of the truncated hexagonal pyramid 62, is denoted as G. The ratio of the aforesaid G and E is within a range of from 1:0.3 to 1:9, preferably 1:0.5; and the ratio of the aforesaid G and F is within a range of from 1:1 to 1:9, preferably 1:2.5. In the present embodiment, the dimension W2 is in the micrometer range. In another embodiment, the dimension W2 can be in the nanometer range.

FIG. 7A shows the cross-section of a column structure having a hexagonal column 71 and a truncated hexagonal pyramid 72 on the hexagonal column 71, and FIG. 7B shows the three-dimensional view of the column structure according to the cross-sectional counterpart. Facet 711 composes the sidewalls of the hexagonal column 71, whereas facet 721 composes the quadrilateral faces of the truncated hexagonal pyramid 72. In particular, facet 721 is a semi-polar plane (S plane), including crystalline orientations of {10 1̅ 2} family, {11 2̅ 2} family, or {1 1̅ 01} family; facet 711 is a non-polar plane (M plane), including crystalline orientations of {1 1̅ 00} family; and facet 731 is a polar plane (C plane), including crystalline orientations of {10001} family. The pillar-like core 701 is covered by the outer shell 702, which can be the regrowth epitaxial layer described herein. A light-emitting layer 703 further covers the outer shell 702 and complies with the shape of the outer shell 702. In the present embodiment, there are nine sets of MQWs in the light-emitting layer 703. The total surface area of the facet 721, which includes six quadrilateral faces of the truncated hexagonal pyramid 72, is denoted as H; the total surface area of the facet 711, which includes six rectangular sidewalls of the hexagonal column 71, is denoted as I; and the total surface area of the facet 731, which includes the hexagonal top of the truncated hexagonal pyramid 72, is denoted as J. The ratio of the aforesaid J and H is within a range of from 1:0.3 to 1:9, preferably 1:7; and the ratio of the aforesaid J and I is within a range of from 1:1 to 1:9, preferably 1:7. In the present embodiment, the dimension W3 is in the micrometer range. In another embodiment, the dimension W3 can be in the nanometer range.

FIG. 8A shows the cross-section of a column structure having a truncated hexagonal pyramid 82, and FIG. 7B shows the three-dimensional view of the column structure according to the cross-sectional counterpart. Facet 821 composes the quadrilateral faces of the truncated hexagonal pyramid 82. In particular, facet 821 is a semi-polar plane (S plane), including crystalline orientations of {10 1̅ 2} family, {11 2̅ 2} family, or {1 1̅ 01} family; facet 831 is a polar plane (C plane), including crystalline orientations of {0001} family. The pillar-like core 801 is covered by the outer shell 802, which can be the regrowth epitaxial layer described herein. A light-emitting layer 803 further covers the outer shell 802 and complies with the shape of the outer shell 802. In the present embodiment, there are two sets of MQWs in the light-emitting layer 803. The total surface area of the facet 821, which includes six quadrilateral faces of the truncated hexagonal pyramid 82, is denoted as K, and the total surface area of the facet 831, which includes the hexagonal top of the truncated hexagonal pyramid 82, is denoted as L. The ratio of the aforesaid L and K is within a range of from 1:3 to 1:9, preferably 1:6. In the present embodiment, the dimension W4 is in the micrometer range. In another embodiment, the dimension W4 can be in the nanometer range.

As can be seen from FIG. 6A to FIG. 8B, the shape control of the column structure is a result of the C plane growth rate. The greater the C plane growth rate, the smaller the portion of the C plane in the grown column structure. Therefore, the C plane growth rate of the column structure shown in FIG. 6A is smaller than that of the column structure shown in FIG. 7A. The C plane growth rate of the column structure shown in FIG. 7A is smaller than that of the column structure shown in FIG. 8A. By modulating the C-plane growth rate, the morphology of the column structure can be altered; hence, the surface area ratio of at least two facets can be changed to tune the luminescence properties, such as CCT and CRI.

FIG. 9A and FIG. 9B illustrate a column structure and the corresponding photoluminescence emission according to the structure shown in FIG. 5A and FIG. 5B. In FIG. 9A, the column structure includes an S plane and an M plane. Due to the fact that indium incorporation rate varies from different crystallography planes and the indium concentration in different regions of the same crystallography plane also changes as a result of gas phase mass transport obeying the boundary conditions set in the column array provided herein, a plurality of regions is marked in FIG. 9A to show the modeling result of the indium concentration profile. Region 901 resides at the top of the hexagonal pyramid. Indium concentration in the MQW structure (5.5 nm well/14.4 nm barrier) is around 19.8 wt %, and an emission of 507 nm can be obtained. Region 902 resides at the bottom of the hexagonal pyramid Indium concentration in the MQW structure (3.4 nm well/14.1 nm barrier) is around 16.4 wt %, and an emission of 460 nm can be obtained. Region 903 resides at the top of the hexagonal column. Indium concentration in the MQW structure (3.5 nm well/16.5 nm barrier) is around 25 wt %, and an emission of 520 nm can be obtained. Region 904 resides at the middle of the hexagonal column. Indium concentration in the MQW structure (3.5 nm well/15.5 nm barrier) is around 14.6 wt %, and an emission of 460 nm can be obtained. Region 905 resides at the bottom of the hexagonal column. Indium concentration in the MQW structure (2.7 nm well/6 nm barrier) is around 11.6 wt %, and an emission of 415 nm can be obtained. The photoluminescence (PL) curve shown in FIG. 9B, demonstrate fitting peaks at 417 nm, 467 nm, 510 nm, and 520 nm, in respect to the column structure of FIG. 9A. The ensemble curve shows the light emitting device possessing column structures in FIG. 9A generates a warm white light, and in one embodiment, the color temperature of the ensemble emission is within a range of from 3000K to 5500K, preferably around 3500K. The PL curve in FIG. 9B is obtained under 300K, using a He—Cd laser (325 nm) outputting 10 mW power.

FIG. 10A and FIG. 10B compare the photoluminescence (PL) spectrum of the two column structures according to the structures shown in FIG. 6B and FIG. 7B, respectively. The PL curve in FIG. 9B is obtained under 300K, using a He—Cd laser (325 nm) outputting 10 mW power. PL spectrum in FIG. 10A corresponds to the structure shown in FIG. 6B, whereas the PL spectrum in FIG. 10B corresponds to the structure shown in FIG. 7B. As can be seen in both PL spectrum, the peak emission wavelengths are around 375 nm, 475 nm, and 525 nm, regardless of the relative intensity between different peaks. This illumination result shows that the emission wavelength cannot be altered upon the change of the ratio of the surface area between different crystalline orientations. Only the color temperature, the relative intensity of each emission wavelength composing the final spectrum, and the color rendering index can be modulated according to the column shape-controlling method provided in the present invention. Therefore, the present invention also provides a method to adjust color temperature or color rendering of a light emitting structure or a light emitting diode. The method includes adjusting the surface area ratio of the at least two facets of different crystalline orientations in the structures provided in the present disclosure.

To adjust color temperature or color rendering of a light emitting structure can also be made possible by changing the composition of the quantum wells in the MQW layer described above. Column structures shown in FIG. 5A and FIG. 5B demonstrate different emission wavelengths under various growth temperature of the quantum well layer. Different growth temperature essentially affects the indium incorporation rate of the indium-containing quantum well, and thus the emission wavelength can be altered as a result of bandgap change. For example, the wavelengths emitted from the M plan and the S plan of the column structure shown in FIG. 5A and FIG. 5B are 538 nm and 482 nm, respectively, under the quantum well growth temperature of 760 degrees Celsius. In another embodiment, the wavelengths emitted from the M plan and the S plan of the column structure shown in FIG. 5A and FIG. 5B are 493 nm and 464 nm, respectively, under the quantum well growth temperature of 780 degrees Celsius. In another embodiment, the wavelengths emitted from the M plan and the S plan of the column structure shown in FIG. 5A and FIG. 5B are 460 nm and 421 nm, respectively, under the quantum well growth temperature of 805 degrees Celsius. In another embodiment, the wavelengths emitted from the M plan and the S plan of the column structure shown in FIG. 5A and FIG. 5B are 452 nm and 402 nm, respectively, under the quantum well growth temperature of 830 degrees Celsius.

Since (1) the variation of the surface area ratio of the at least two facets of different crystalline orientations and (2) the adjustment of the quantum well composition in the structures provided in the present disclosure both lead to color temperature or color rendering adjustment in a light emitting structure or a light emitting diode, one embodiment presented in the instant disclosure is to utilize either method (1) or (2) to achieve the purpose of CRI and CCT adjustment. In another embodiment, method (1) and (2) can be utilized concurrently to achieve the purpose of CRI and CCT adjustment.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor column structure, comprising:
a light emitting layer; and
at least two facets with different crystalline orientations;
wherein the surface area ratio of the at least two facets is in a range of from 1:0.1 to 1:10.

2. The semiconductor column structure according to claim 1, wherein the light emitting layer comprises a plurality of sets of multi-quantum wells.

3. The semiconductor column structure according to claim 2, wherein different facets of the column structure are able to emit different wavelengths.

4. The semiconductor column structure according to claim 3, wherein different regions of the facets of the column structure are able to emit different wavelengths.

5. The semiconductor column structure according to claim 1, wherein one of the at least two facets is a semi-polar plane.

6. The semiconductor column structure according to claim 4, wherein two of the at least two facets comprise an S plane and a C plane, and wherein the S plane includes {10 1̅ 2} family, {11 2̅ 2} family, and {1 1̅ 01} family.

7. The semiconductor column structure according to claim 4, wherein two of the at least two facets comprise an S plane and an M plane, and wherein the S plane includes {10 1̅ 2} family, {11 2̅ 2} family, and {1 1̅ 01} family.

8. The semiconductor column structure according to claim 4, wherein three of the at least two facets comprise an M plane, an S plane, and a C plane, and wherein the S plane includes {10 1̅ 2} family, {11 2̅ 2} family, and {1 1̅ 01} family.

9. The semiconductor column structure according to claim 6, wherein the surface area ratio of the C plane and the S plane is in a range of from 1:3 to 1:9.

10. The semiconductor column structure according to claim 7, wherein the surface area ratio of the S plane and the M plane is in a range of from 1:1 to 1:3.

11. The semiconductor column structure according to claim 8, wherein the surface area ratio of the C plane and the S plane is in a range of from 1:0.3 to 1:9, and the surface area ratio of the C plane and the M plane is in a range of from 1:1 to 1:9.

12. The semiconductor column structure according to claim 1, wherein the diameter of the column is in nanometer range or in micrometer range.

13. A light emitting diode structure, comprising:
a semiconductor column array;
a cathode electrically coupled to a first conductive type of the column array; and
an anode electrically coupled to a second conductive type of the column array;
wherein each column of the semiconductor column array comprises:
a light emitting layer; and
at least two facets with different orientations;
wherein the surface area ratio of the at least two facets is in a range of from 1:10 to 10:1.

14. The light emitting diode structure according to claim 13, wherein the light emitting layer comprises a plurality of sets of multi-quantum wells.

15. The light emitting diode structure according to claim 14, wherein different sets of the multi-quantum wells are able to emit different wavelengths.

16. The light emitting diode structure according to claim 13, wherein one of the at least two facets is a semi-polar plane.

17. The light emitting diode structure according to claim 16, wherein the at least two facets comprise the combinations of a C plane and an S plane, an S plane and an M plane, or an S plane, a C plane, and an M plane, and wherein the S plane includes {10 1̅ 2} family, {11 2̅ 2} family, and {1 1̅ 01} family.

18. The light emitting diode structure according to claim 17, wherein the surface area ratio of the combination of the C plane and the S plane is in a range of from 1:3 to 1:9.

19. The light emitting diode structure according to claim 17, wherein the surface area ratio of the combination of the S plane and the M plane is in a range of from 1:1 to 1:3.

20. The light emitting diode structure according to claim 17, wherein the surface area ratio of the C plane and the S plane in the combination of the M plane, S plane, and C plane is in a range of from 1:0.3 to 1:9, and the surface area ratio of the C plane and the M plane in the combination of the M plane, S plane, and C plane is in a range of from 1:1 to 1:9.

21. The light emitting diode structure according to claim 13, wherein the diameter of the column is in nanometer range or in micrometer range.

22. The light emitting diode structure according to claim 13, wherein the different facets of the column emit different wavelengths.

23. The light emitting diode structure according to claim 13, wherein the light emitted from the semiconductor column array comprises a color temperature within a range of from 3000K to 5500K.

24. A method to adjust color temperature or color rendering of a light emitting diode as claim 13 comprising of adjusting the surface area ratio of the at least two facets, adjusting the composition of the light emitting layer, or the combination thereof.

25. The method according to claim 24, wherein adjusting the surface area ratio of the at least two facets and adjusting the composition of the light emitting layer comprise changing at least one of the following: growth temperature, III/V ratio, and growth pressure.
